(19) United States
(12) Patent Application Publication
(10) Pub. No.: US 2015/0200685 A1
(43) Pub. Date: Jul. 16, 2015

(54) RECORDING AND REPRODUCING DEVICE, ERROR CORRECTION METHOD, AND CONTROL DEVICE

(71) Applicant: FUJITSU LIMITED, Kawasaki-shi (JP)

(72) Inventors: YOKO KAWANO, Yokohama (JP); Terumasa Haneda, Machida (JP)

(73) Assignee: Fujitsu Limited, Kawasaki (JP)

(21) Appl. No.: 14/668,410

(22) Filed: Mar. 25, 2015

Related U.S. Application Data
(63) Continuation of application No. PCT/JP2012/077160, filed on Oct. 19, 2012.

(51) Int. Cl. H03M 13/05; G06F 11/10

(52) U.S. Cl. CPC H03M 13/05; G06F 11/10

(57) ABSTRACT

A recording and reproducing device includes a plurality of data storing units, a control unit, a first error detection-and-correction unit, and a second error detection-and-correction unit. The control unit creates stripe data with a predetermined write capacity, creates a redundant group, associates a plurality of pieces of stripe data, and controls the writing of the associated data into each of the plurality of the data storing units. The first error detection-and-correction unit detects whether an error is present in each of the pieces of the stripe data, and corrects the stripe data. The second error detection-and-correction unit groups the second error correction code and the pieces of the stripe data, creates a plurality of error correction groups, detects whether an error is present in each of the pieces of the split stripe data in the same error correction group, and corrects the split stripe data.

### CROSS-REFERENCE TO RELATED APPLICATION

This application is a continuation of International Application No. PCT/JP2012/077160, filed on Oct. 19, 2012 and designating the U.S., the entire contents of which are incorporated herein by reference.

### FIELD

The embodiments discussed herein are related to a recording, reproducing device and the like.

### BACKGROUND

In recent years, NAND type flash memories (hereinafter, referred to as “NAND flash”) are widely used as nonvolatile storage media that are well balanced in terms of the access performance, the capacity, and the cost. However, the error rate of NAND flash is relatively high when compared with other nonvolatile storage media, which is the factor that prevents reliability.

Accordingly, controllers that control NAND flash attach error correcting codes (ECCs) to data to be written in the NAND flash and perform error correction by using the ECCs when the data is read.

Furthermore, there is a known technology of ECC circuits that perform error correction on read data by using a plurality of error correction codes (for example, see Patent Document 1). For example, an ECC circuit performs first error correction on read data by using first error correction codes (Hamming codes). Then, the ECC circuit further performs second error correction on the results of the first error correction by using second error correction codes (BHC codes). Furthermore, the ECC circuit further performs third error correction on the results of the second error correction by using third error correction codes (RS codes).

Furthermore, as a measure against the high error rate, for example, the controller that controls the NAND flash writes data that uses the structure of Redundant Array of Inexpensive Disks (RAID) 5 into the NAND flash. The configuration of RAID 5 mentioned here is the configuration in which parity is attached to a plurality of pieces of stripe data that are obtained from splitting data into a plurality of pieces of data. Then, when the data is read, the controller performs the error correction by using the parity.
Patent Document 1: Japanese Laid-open Patent Publication No. 2009-211209
Patent Document 2: Japanese Laid-open Patent Publication No. 9-218754

However, with the measure against the error rate of the related NAND flash, there is a problem in that it is not improve the data recovery rate of the NAND flash.

For example, in recent years, for NAND flash, with the development of miniaturization or the plurality of valued structures, the reliability is decreased, such as bits are easily corrupted. Accordingly, error correction performed by using ECCs is difficult. Furthermore, even if data is structured in RAID 5, if errors have occurred in a plurality of pieces of stripe data, error correction performed by using parity is not available. Accordingly, there is a demand to increase the data recovery rate of NAND flash other than the measure against the error rate of the related NAND flash.

The problem described above does not only occur in the NAND flash but also similarly occurs in other storage media.

### SUMMARY

According to an aspect of the embodiments, a recording and reproducing device includes: a plurality of data storing units; a control unit that creates stripe data with a predetermined write capacity by attaching a first error correction code to write data, that creates a redundant group by attaching a second error correction code to a predetermined number of pieces of the stripe data, that associates a plurality of pieces of stripe data belonging to the same redundant group with the second error correction code, and that controls the writing of the associated data into each of the plurality of the data storing units; a first error detection-and-correction unit that detects, by using the second error correction code, whether an error is present in each of the pieces of the stripe data, which are read from each of the data storing units and belong to the same redundant group, and that corrects the stripe data in which the error is present; and a second error detection-and-correction unit that groups, for creation blocks of the first error correction code, the second error correction code and the pieces of the stripe data that are read from each of the data storing units and that belong to the same redundant group, that creates a plurality of error correction groups each of which includes a plurality of pieces of split stripe data and a split second error correction code, that detects, by using the split second error correction code, whether an error is present in each of the pieces of the split stripe data in the same error correction group, and that corrects the split stripe data in which the error is present.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic diagram illustrating the hardware configuration of a storage device according to a first embodiment;

FIG. 2A is a schematic diagram illustrating an example of the configuration of a NAND flash;

FIG. 2B is a schematic diagram illustrating the data structure of data stored in the NAND flash;

FIG. 3 is a schematic diagram illustrating the grouping of read data according to the first embodiment;

FIG. 4 is a schematic diagram illustrating a specific example of data correction according to the first embodiment;

FIG. 5 is a flowchart illustrating the flow of a data writing process;

FIG. 6 is a flowchart illustrating the flow of a data correction process;

FIG. 7 is a schematic diagram illustrating the hardware configuration of a storage device according to a second embodiment;

FIG. 8 is a schematic diagram (No. 1) illustrating a specific example of data correction according to the second embodiment;

FIG. 9 is a schematic diagram (No. 2) illustrating a specific example of data correction according to the second embodiment; and

FIG. 10 is a flowchart illustrating the flow of a data correction process.

### DESCRIPTION OF EMBODIMENTS

Preferred embodiments will be explained with reference to accompanying drawings. The present invention is not limited to these embodiments. Furthermore, the embodiments can be used in any appropriate combination as long as the processes do not conflict with each other. In the following embodiments, a description is given of a case in which the present invention is applied to a storage device.

### [a] First Embodiment

### Configuration of a Storage Device According to a First Embodiment

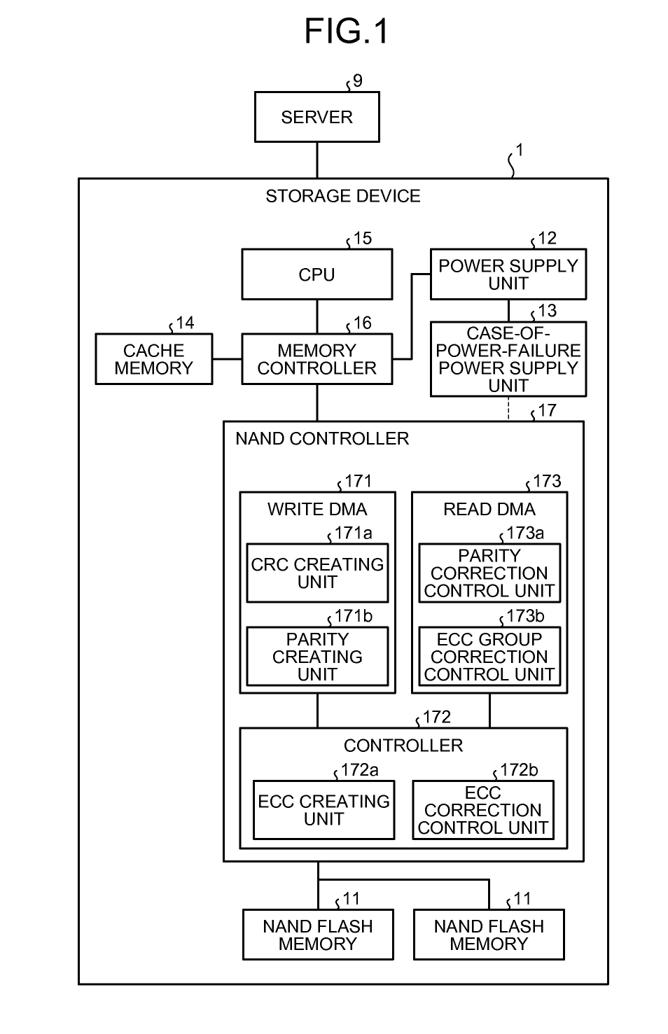

FIG. 1 is a schematic diagram illustrating the hardware configuration of a storage device according to a first embodiment. As illustrated in FIG. 1, a storage device 1 is connected to a server 9. The storage device 1 includes a NAND flash memory (hereinafter, referred to as “NAND flash”) 11, a power supply unit 12, a case-of-power-failure power supply unit 13, and a cache memory 14. Furthermore, the storage device 1 includes a CPU 15, a memory controller 16, and a NAND controller 17. Furthermore, the NAND controller 17 cooperates with the NAND flash 11, thus operating as, for example, a recording and reproducing device. These devices included in the storage device 1 may also be included in a controller module (CM). Furthermore, the storage device 1 is connected to the server 9. Based on the instruction from the server 9, the storage device 1 writes and reads data to and from the NAND flash memory 11.

The NAND flash 11 is a nonvolatile semiconductor memory. The NAND flash 11 stores therein user data or a program from the server 9. Specifically, the NAND flash 11 is used as a storage medium (storage) that is the storage destination of data received from the server 9.

The NAND flash 11 stores therein a plurality of pieces of stripe data obtained by splitting user data into pieces and stores therein parity that is attached to a predetermined number of pieces of stripe data. Namely, the user data is stored in the NAND flash 11 with the structure of RAID 5. FIG. 1 illustrates a case in which two pieces of NAND flash 11 are mounted; however, three or more pieces NAND flash 11 may also be mounted.

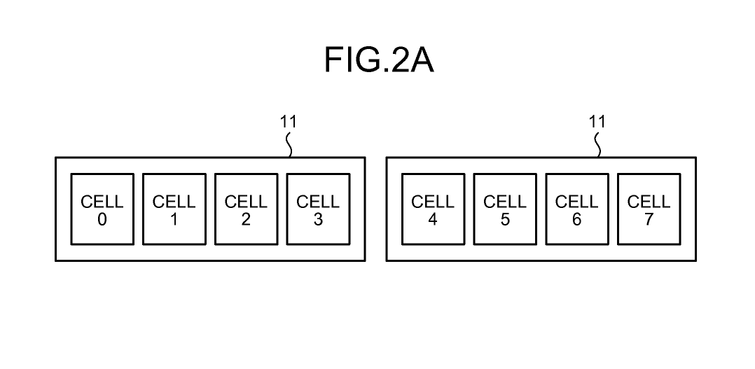

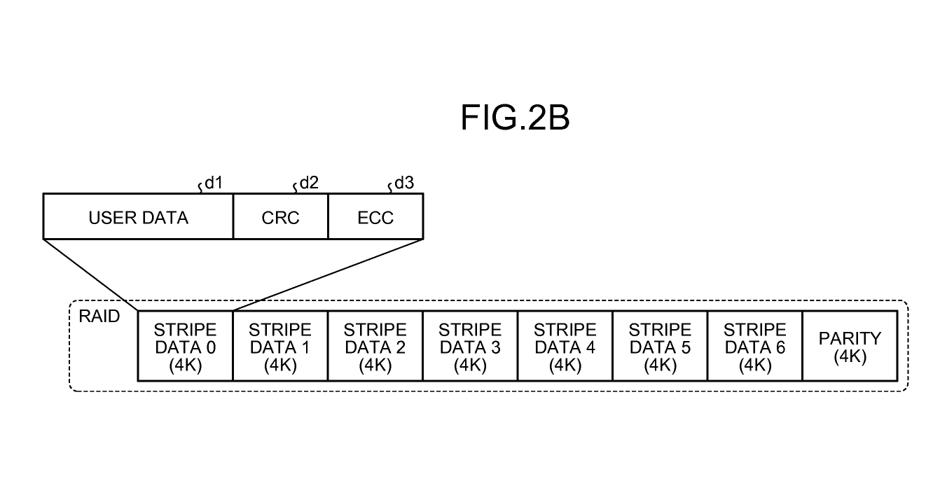

In the following, the configuration of the NAND flash 11 will be described with reference to FIG. 2A. FIG. 2A is a schematic diagram illustrating an example of the configuration of a NAND flash. As illustrated in FIG. 2A, a single piece of the NAND flash 11 includes four cells. In a single cell, a single piece of stripe data is stored from among a plurality of pieces of stripe data of the user data. For example, if the NAND controller 17, which will be described later, writes user data, the NAND controller 17 issues a write command for writing stripe data, which is targeted for the writing, to a writing unit that is associated with each of the cells in the NAND flash 11. The writing unit that has received the write command writes the stripe data that is associated with the write command to the cell. In contrast, if the NAND controller 17 reads user data, the NAND controller 17 issues a read command for reading stripe data, which is targeted for the writing, to a reading unit that is associated with each of the cells in the NAND flash 11. The reading unit that has received the read command reads the stripe data that is associated with the read command and transmits the read stripe data to the NAND controller 17. The NAND flash 11 having such function implements the structure of RAID 5 by each piece of stripe data stored in a plurality of cells.

Furthermore, because a single piece of the NAND flash 11 includes four cells, each of the pieces of stripe data in different RAIDs may also be stored in a single piece of the NAND flash. For example, stripe data 0 in a first RAID, stripe data 0 in a second RAID, stripe data 0 in a third RAID, and stripe data 0 in a fourth RAID are stored in the first NAND flash 11. Stripe data 1 in a first RAID, stripe data 1 in a second RAID, stripe data 1 in a third RAID, and stripe data 1 in a fourth RAID are stored in the second NAND flash 11. Because the data is stored in this manner, even if one of the pieces of the NAND flash 11 fails, it is possible to restore the data stored in the failed NAND flash 11 by using the data stored in the other one of the NAND flash 11.

In the following, the data structure of the user data stored in the NAND flash 11 will be described with reference to FIG. 2B. FIG. 2B is a schematic diagram illustrating the data structure of data stored in the NAND flash. As illustrated in FIG. 2B, the user data stored in the NAND flash includes a plurality of pieces of stripe data and parity that is associated with the plurality of pieces of the stripe data. In this case, RAID 5 is constructed by seven pieces of stripe data and the parity. Each of the pieces of the stripe data and the parity is data with 4 kilo bytes (KB) that is a unit of writing to each piece of the NAND flash 11. Then, each piece of the stripe data includes user data d1, cyclic redundancy check (CRC) d2, and an Error Correcting Code (ECC) d3. The CRC d2 is an error detection code that detects an error of the user data d1 and the ECC d3 is an error correction code that corrects the error of the user data d1. For example, the stripe data 0 to 3 are stored in the cells 0 to 3, respectively, illustrated in FIG. 2A. The stripe data 4 to 6 and the parity are stored in the cells 4 to 7, respectively, illustrated in FIG. 2A. Furthermore, the CRC d2 is created by a CRC creating unit 171a, which will be described later, the ECC d3 is created by an ECC creating unit 172a, which will be described later, and the parity is created by a parity creating unit 171b, which will be described later.

A description will be given here by referring back to FIG. 1. The power supply unit 12 supplies, in the normal operation, electrical power to the storage device 1. The normal operation mentioned here is a state in which, after power supply of the storage device 1 is turned on, the operation continues without the occurrence of power failure. A case-of-power-failure power supply unit 13 supplies electrical power to the NAND flash 11, the cache memory 14, the CPU 15, the memory controller 16, and the NAND controller 17 when a power failure occurs. The case-of-power-failure power supply unit 13 includes therein a condenser and accumulates, in the normal operation, the electrical power from the power supply unit 12 in the condenser. The case-of-power-failure power supply unit 13 supplies the electrical power accumulated in the condenser when a power failure occurs.

The cache memory 14 is, for example, a volatile memory, such as a dual inline memory module (DIMM), a double date rate synchronous DRAM (DDR SDRAM), or the like. The cache memory 14 temporarily stores therein user data that is written in the NAND flash 11 in accordance with a write instruction received from the server 9. Furthermore, the cache memory 14 temporarily stores therein the user data that is read from the NAND flash 11 in accordance with a read instruction received from the server 9.

The central processing unit (CPU) 15 controls the entirety of the storage device 1. For example, the CPU 15 controls the interface with the server. The memory controller 16 performs, in accordance with an instruction received from the server 9, input/output control of data with respect to the cache memory 14. Furthermore, in the description above, the CPU 15 and the memory controller 16 has independent configuration; however, the CPU 15 and the memory controller 16 may also be integrated into a CPU that is embedded in the memory controller.

The memory controller 16 controls data transfer between the cache memory 14 and the NAND flash 11 without passing through the CPU 15. The NAND controller 17 performs input/output control of data to and from the NAND flash 11. Furthermore, the NAND controller 17 includes a write direct memory access (DMA) 171, a controller 172, and a read DMA 173. The write DMA 171 controls transfer of write data from the cache memory 14 to the NAND flash 11. The read DMA 173 controls transfer of read data from the NAND flash 11 to the cache memory 14. The controller 172 controls the write data and the read data.

The write DMA 171 includes the CRC creating unit 171a and the parity creating unit 171b.

When data is written in the NAND flash 11, the CRC creating unit 171a splits the data into a plurality of pieces of data in order to structure the data with RAID 5 and creates a CRC that is used for error detection for each piece of the split data. Then, the CRC creating unit 171a attaches the created CRC to the associated split data. The split data corresponds to stripe data. Hereinafter, the split data is referred to as the stripe data.

The parity creating unit 171b creates parity that is used in RAID 5 by associating the parity with a predetermined number of pieces of stripe data. The parity is used as an error correction code. Then, the parity creating unit 171b uses the created parity as a single piece of stripe data and uses the created parity together with the predetermined number of pieces of the stripe data as write data. By doing so, for example, by using a predetermined number of pieces of the stripe data and the associated parity therewith, the write data becomes 4 KB arrayed data that is a unit of writing to the NAND flash 11. The predetermined number of pieces of data is, for example, seven; however, the number of pieces of data may also be six or eight as long as RAID 5 can be structured. Furthermore, the parity creating unit 171b is an example of a control unit.

The controller 172 includes the ECC creating unit 172a and an ECC correction control unit 172b.

The ECC creating unit 172a creates, for each ECC creation block, an ECC, i.e., each piece of the stripe data, of the write data. The ECC creation block mentioned here is a unit of ECC created for the ECC check. The ECC creation block depends on the correction capability of ECC determined by specifications of the NAND flash 11 and is, for example, 224 bytes. The ECC used in this case is 16 bytes. The ECC creating unit 172a writes, together with the created ECC, the write data into the NAND flash 11. The ECC creating unit 172a is an example of the control unit.

When the ECC correction control unit 172b reads the data that has been written by the ECC creating unit 172a, the ECC correction control unit 172b performs an ECC check on the read data that has been read. If the result of the ECC check indicates that no error has been detected, the ECC correction control unit 172b outputs the read data to the read DMA 173 without processing anything. In contrast, if the result of the ECC check indicates that an error has been detected and the error is a correctable error, the ECC correction control unit 172b corrects the error by using the ECC and outputs the corrected read data to the read DMA 173. Furthermore, the timing at which the written data is read is, for example, when a read instruction to read the data is issued by the server.

Furthermore, if the result of the ECC check indicates that an error has been detected and the error is an uncorrectable error, the ECC correction control unit 172b outputs the position of the ECC creation block in which the error has been detected to the read DMA 173. At this point, the ECC correction control unit 172b outputs the read data to the read DMA 173 without processing anything. The ECC correction control unit 172b is an example of a position output unit.

The read DMA 173 includes a parity correction control unit 173a and an ECC group correction control unit 173b.

The parity correction control unit 173a performs a CRC check on the read data that is output from the ECC correction control unit 172b. If the result of the CRC check indicates that no error has been detected, the parity correction control unit 173a outputs the read data in which no error has been detected to the memory controller 16.

Furthermore, if the result of the CRC check indicates that an error has been detected, the parity correction control unit 173a determines whether the error can be corrected by the parity in RAID. If the parity correction control unit 173a determines that the error can be corrected by the parity in the RAID, the parity correction control unit 173a corrects, by using the parity, the stripe data in which the error has been detected. Namely, if the number of pieces of stripe data in which an error has been detected by using the CRC check is only one, the parity correction control unit 173a corrects the subject stripe data by using both parity and another piece of stripe data. Then, after the parity correction control unit 173a corrects the stripe data in which the error has been detected, the parity correction control unit 173a outputs the read data including the corrected stripe data to the memory controller 16. Furthermore, if two or more pieces of stripe data in each of which an error has been detected by the CRC check is present, because the error position is not able to be specified by the parity correction control unit 173a, the errors are not able to be corrected by using the parity. Furthermore, the parity correction control unit 173a is an example of a first error detection-and-correction unit.

If errors are detected in two or more pieces of stripe data in the read data, the ECC group correction control unit 173b groups ECC creation blocks that are obtained from each of the pieces of the stripe data in the read data. The reason for grouping the ECC creation blocks is that the position in which an error is detected can be specified. Namely, because the ECC correction control unit 172b outputs the position of the ECC creation block in which the error has been detected, the ECC group correction control unit 173b can specify an error position in a group by using the output position. Hereinafter, a group created by grouping ECC creation blocks is referred to as an “ECC group”.

Furthermore, the ECC group correction control unit 173b controls error correction by using parity included in an ECC group for each ECC group. For example, the ECC group correction control unit 173b acquires the position of the ECC creation block that is output by the ECC correction control unit 172b and in which an error has been detected. Then, the ECC group correction control unit 173b detects an ECC group that includes the position of the acquired ECC creation block. Then, the ECC group correction control unit 173b determines whether the error can be corrected, by a unit of the detected ECC group, by using the parity that is included in the subject ECC group. If the ECC group correction control unit 173b determines that the error can be corrected by using the parity included in the subject ECC group, the ECC group correction control unit 173b corrects the ECC creation block in which the error has been detected. Namely, if the number of positions of the ECC creation block in which the error has been detected is only one, the ECC group correction control unit 173b corrects the ECC creation block at the subject potion by using the parity that is used in the same group.

Furthermore, when the ECC group correction control unit 173b corrects the ECC creation block, the ECC group correction control unit 173b outputs the read data that includes the corrected ECC creation block to the memory controller 16. Furthermore, if the number of positions of the ECC creation blocks in each of which the error has been detected is equal to or greater than two in the ECC group, the ECC group correction control unit 173b is not able to correct the error by using the parity that is included in the same ECC group. Furthermore, the ECC group correction control unit 173b is an example of a second error detection-and-correction unit.

Grouping of Read Data

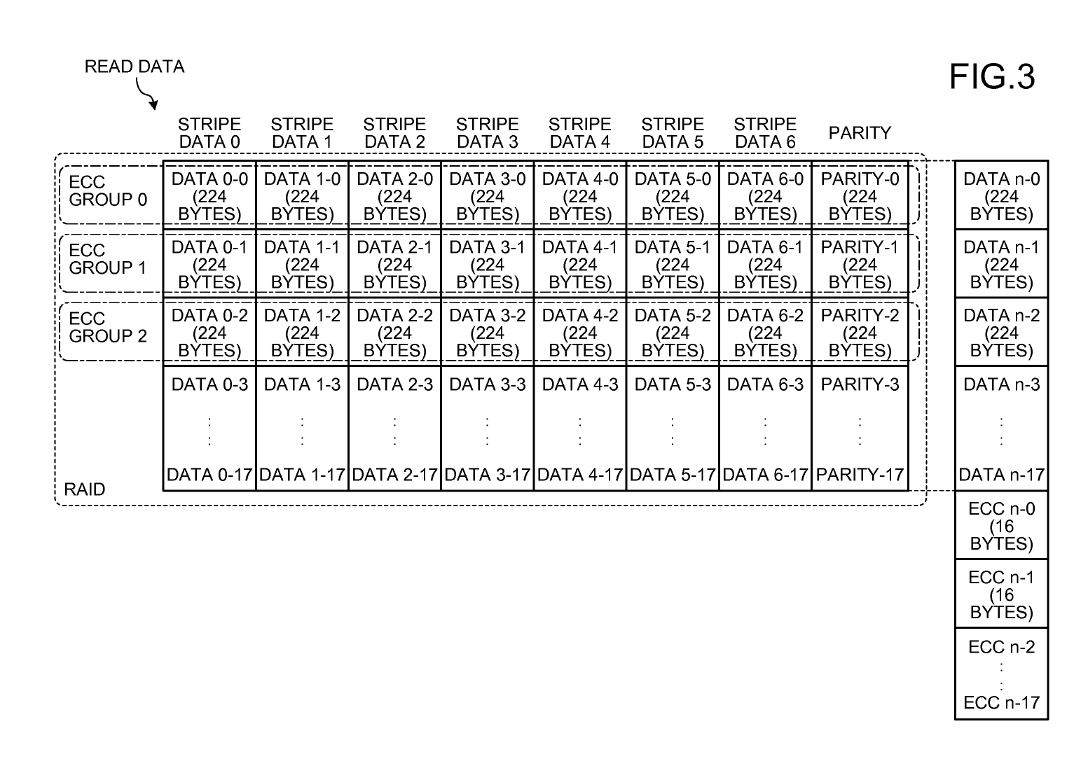

In the following, grouping of read data that is created by the ECC group correction control unit 173b will be described with reference to FIG. 3. FIG. 3 is a schematic diagram illustrating the grouping of read data according to the first embodiment. As described in FIG. 3, the read data has the structure of RAID 5 in which stripe data 0 to 6 and parity are included. Each of the pieces of the stripe data and the parity is represented by 224 bytes that corresponds to an ECC creation block. The ECC is created for each ECC creation block. For example, the stripe data 0 is represented for each ECC creation block, i.e., 224 bytes, and, in this case, is represented by data 0-0, data 0-1, . . . , and data 0-17. Each ECC is created for data 0-0 to data 0-17. Similarly, the parity is also represented for each ECC creation block, i.e., 224 bytes, and, in this case, is represented by parity-0, parity-1, . . . , and parity-17. Each ECC is created for parity-0 to parity-17. Each ECC is represented by 16 bytes.

Then, the ECC group correction control unit 173b groups ECC creation blocks each of which is obtained from the pieces of the stripe data and the parity included in the read data. Here, it is assumed that the ECC group correction control unit 173b sets the data 0-0 in the stripe data 0, the data 1-0 in the stripe data 1, the data 2-0 in the stripe data 2, . . . , and the parity-0 in the parity into an ECC group 0. The ECC group correction control unit 173b sets the data 0-1 in the stripe data 0, the data 1-1 in the stripe data 1, the data 2-1 in the stripe data 2, . . . , and the parity-1 in the parity into an ECC group 1.

Specific Example of Data Correction

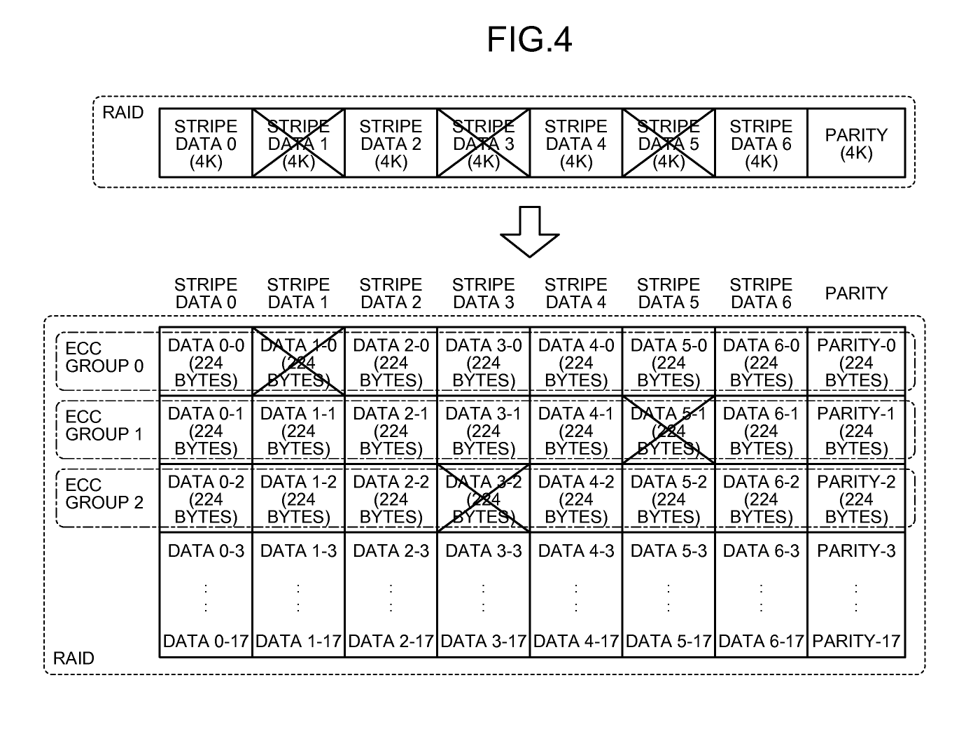

A specific example of data correction performed on the read data in which grouping is set in this way will be described with reference to FIG. 4. FIG. 4 is a schematic diagram illustrating a specific example of data correction according to the first embodiment. As illustrated in an upper portion of FIG. 4, it is assumed that, in the read data, the number of pieces of the stripe data in each of which an error has been detected by the CRC check is equal to or greater than two, such as the stripe data 1, the stripe data 3, and the stripe data 5. Accordingly, the parity correction control unit 173a is not able to correct the errors by using the parity itself in the RAID.

As illustrated in the lower portion of FIG. 4, the ECC group correction control unit 173b controls the error correction for each ECC group by using the parity that is included in an ECC group. Here, the ECC group correction control unit 173b acquires the position of the ECC creation block in which the error has been detected as the position of the data 1-0 in the stripe data 1. Then, the ECC group correction control unit 173b detects the ECC group 0 that includes the acquired position of the data 1-0. Because the number of positions of the ECC creation block in which the error has been detected is only one, i.e., the data 1-0, in the ECC group 0, the ECC group correction control unit 173b corrects the data 1-0 by using the other pieces of the data and the parity-0 in the ECC group 0.

Then, the ECC group correction control unit 173b acquires the position of the ECC creation block in which the error has been detected as the position of data 3-2 in the stripe data 3. Then, the ECC group correction control unit 173b detects the ECC group 2 that includes the acquired position of the data 3-2. Because the number of positions of the ECC creation block in which the error has been detected is only one, i.e., the data 3-2, in the ECC group 2, the ECC group correction control unit 173b corrects the data 3-2 by using the other pieces of the data and the parity-2 in the ECC group 2.

Then, the ECC group correction control unit 173b acquires the position of the ECC creation block in which the error has been detected as the position of data 5-1 in the stripe data 5. Then, the ECC group correction control unit 173b detects the ECC group 1 that includes the acquired position of the data 5-1. Because the number of positions of the ECC creation block in which the error has been detected is only one, i.e., the data 5-1, in the ECC group 1, the ECC group correction control unit 173b corrects the data 5-1 by using the other pieces of the data and the parity-1 in the ECC group 1.

In this way, even if the number of pieces of the stripe data in each of which an error has been detected in the read data is equal to or greater than two, the ECC group correction control unit 173b can correct the error in the read data unless the positions of the ECC creation blocks in each of which the error has been detected are present in the same ECC group. Here, another method may also be conceivably used as error correction of the read data in which a unit of RAID is increased by reducing the size of the stripe stored in the RAID and an error in the read data is corrected by using parity in the RAID. However, if the size of the stripe in the RAID is reduced, the number of redundant bits of CRC or parity is accordingly increased and thus the performance at the time of the writing operation is decreased. Therefore, an error is corrected by using an ECC group without changing the size of a stripe in RAID, which improves the reliability of the NAND flash 11 without decreasing the performance at the time of the writing operation.

Flowchart of a Data Writing Process Performed on and a Data Correction Process

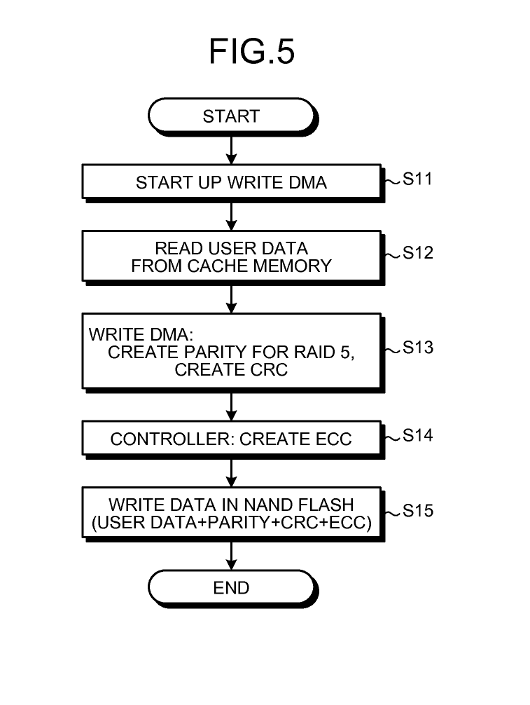

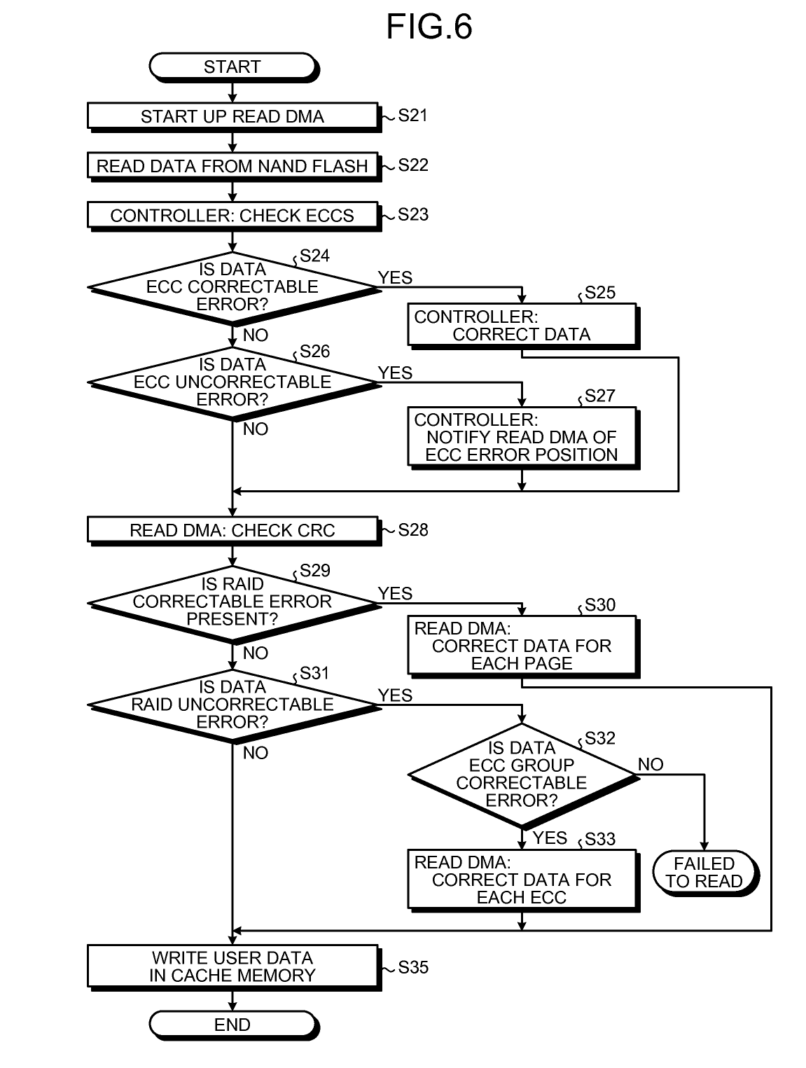

In the following, a data correction process according to the first embodiment will be described with reference to FIGS. 5 and 6. Here, a description will be given of an example of a writing process in which, if a write instruction to data is issued by the server 9, data in the cache memory 14 is written in accordance with the write instruction. Furthermore, a description will be given of a data correction process in which, if a read instruction of data is issued by the server 9, data that is read from the NAND flash 11 in accordance with the read instruction is corrected. FIG. 5 is a flowchart illustrating the flow of a data writing process. FIG. 6 is a flowchart illustrating the flow of a data correction process.

As illustrated in FIG. 5, the CPU 15 that has received a write instruction from the server 9 starts up the write DMA 171 (Step S11). Then, the CPU 15 reads user data from the cache memory 14 in accordance with the write instruction from the server 9 (Step S12).

Then, for the read user data, the write DMA 171 creates parity used in RAID 5 and creates a CRC (Step S13). For example, the CRC creating unit 171a in the write DMA 171 splits the user data into a plurality of pieces of stripe data in order to construct RAID 5 and creates a CRC for each of the split pieces of the stripe data. Then, the parity creating unit 171b in the write DMA 171 associates the CRC with a predetermined number of pieces of the stripe data and creates parity that is used in RAID 5. Then, the parity creating unit 171b uses the created parity as a single piece of stripe data and uses the created parity and the predetermined number of pieces of stripe data as a piece of write data.

Subsequently, the controller 172 creates an ECC for the write data (Step S14). For example, the ECC creating unit 172a in the controller 172 creates ECCs for ECC creation blocks by using each piece of the stripe data in the write data.

Then, the controller 172 writes the data to the NAND flash 11. The data mentioned here is, specifically, the user data, the parity the CRC, and the ECC (Step S15). Namely, the ECC creating unit 172a in the controller 172 writes the write data to the NAND flash 11 together with the created ECC.

By doing so, the user data that is stored in the cache memory 14 is written in the NAND flash 11 in accordance with the write instruction from the server 9.

As illustrated in FIG. 6, the CPU 15 that has received a read instruction from the server 9 starts up the read DMA 173 (Step S21). Then, the CPU 15 reads data from the NAND flash 11 (Step S22).

Then, the ECC correction control unit 172b in the controller 172 performs the ECC check on the read data (Step S23) and determines whether, for the read data, an error is a correctable error by using the ECC (ECC correctable error) (Step S24). If it is determined that the error is an ECC correctable error (Yes Step S24), the ECC correction control unit 172b corrects the data by using the ECC (Step S25). Then, the ECC correction control unit 172b proceeds to Step S28 in order to perform the CRC check. This is because an error may be detected by a CRC even if the data has been corrected by the ECC.

In contrast, if it is determined that the error is not an ECC correctable error (No at Step S24), the ECC correction control unit 172b in the controller 172 determines whether the error is uncorrectable error by using the ECC (ECC uncorrectable error) (Step S26). If it is determined that the error is an ECC uncorrectable error (Yes Step S26), the ECC correction control unit 172b in the controller 172 notifies the read DMA 173 of the position of the ECC creation block in which the error (fault) has been detected (Step S27). Then, the ECC correction control unit 172b proceeds to Step S28 in order to perform the CRC check.

In contrast, if it is determined that the error is not an ECC uncorrectable error (No at Step S26), i.e., if it is determined by the ECC that no error is present, the ECC correction control unit 172b proceeds to Step S28 in order to perform the CRC check. This is because an error may be detected by a CRC even if it is determined that no error is present in the data by using the ECC.

Subsequently, the read DMA 173 performs the CRC check on the read data or the corrected read data (Step S28) and determines whether an error is a correctable error that can be corrected by using the parity in the RAID (RAID correctable error) (Step S29).

If it is determined that the error is a RAID correctable error (Yes at Step S29), the parity correction control unit 173a in the read DMA 173 corrects the data for each page (in a unit of stripe) (Step S30). Namely, if there is only a single piece of the stripe data in which an error has been detected by the CRC check, the parity correction control unit 173a corrects the subject stripe data by using both the other pieces of the stripe data and the parity. The parity correction control unit 173a outputs the corrected read data to the memory controller 16. Then, the parity correction control unit 173a proceeds to Step S35.

In contrast, if it is determined that an error is not a RAID correctable error (No at Step S29), the parity correction control unit 173a determines whether the error is an uncorrectable error by using the parity in the RAID (RAID uncorrectable error) (Step S31). Namely, the parity correction control unit 173a determines whether the number of pieces of the stripe data in each of which an error has been detected by the CRC check is equal to or greater than two.

If it is determined that the error is not a RAID uncorrectable error (No at Step S31), the parity correction control unit 173a outputs the read data to the memory controller 16 because no error is detected. Then, the parity correction control unit 173a proceeds to Step S35.

In contrast, if it is determined that the error is a RAID uncorrectable error (Yes at Step S31), because the number of pieces of the stripe data in each of which an error has been detected by the CRC check is equal to or greater than two, the parity correction control unit 173a is not able to specify the position of the error and thus determines that an error is not able to be corrected by using the parity.

Then, the ECC group correction control unit 173b in the read DMA 173 determines whether the error is a correctable error by using an ECC group (ECC group correctable error) (Step S32). For example, the ECC group correction control unit 173b acquires the position of the ECC creation block that is notified by the ECC correction control unit 172b and in which the error is present. Then, the ECC group correction control unit 173b detects an ECC group that includes the acquired position of the ECC creation block. Then, the ECC group correction control unit 173b determines whether the error can be corrected, within the detected ECC group, by using the parity that is included in the subject ECC group. Namely, the ECC group correction control unit 173b determines whether the number of ECC creation blocks in each of which an error is present in the detected ECC group is equal to or greater than two.

If it is determined that the error is an ECC group correctable error (Yes at Step S32), the ECC group correction control unit 173b corrects data for each ECC creation block (Step S33). For example, by using the parity included in the ECC group, the ECC group correction control unit 173b corrects the ECC creation block in which the error has been detected. Namely, if the number of positions of the ECC creation block in which an error has been detected is only one in an ECC group, the ECC group correction control unit 173b corrects the ECC creation block at the subject position by using the parity that is in the same group. Then, the ECC group correction control unit 173b outputs the corrected read data to the memory controller 16. Then, the ECC group correction control unit 173b proceeds to Step S35.

In contrast, if it is determined that the error is not an ECC group correctable error (No Step S32), the ECC group correction control unit 173b determines that the error is an uncorrectable error by the ECC group. Namely, because the number of positions of the ECC creation blocks in each of which an error has been detected is equal to or greater than two in the ECC group, the ECC group correction control unit 173b determines that the errors are not able to be corrected by using the parity stored in the same ECC group. Consequently, the process has been ended as a failure to read data.

At Step S35, the memory controller 16 writes user data in the cache memory 14 (Step S35). Namely, the memory controller 16 writes the read data that is output from the read DMA 173 into the cache memory 14 and then outputs the read data to the server 9. Consequently, the process has been ended as the completion of the reading.

By doing so, the user data that is written in the NAND flash 11 is correctly written in the cache memory 14 even if an error is present in a reading process. Furthermore, the memory controller 16 can convey the correct user data to the server 9.

### Advantage of the First Embodiment

According to the first embodiment described above, when the write DMA 171 writes data in the NAND flash 11, the write DMA 171 creates a CRC for each stripe that is obtained by splitting data into pieces of data; attaches a CRC; creates parity by associating the parity with a predetermined number of pieces of consecutive stripe. Then, the ECC creating unit 172a creates an ECC for each ECC creation block by using each stripe in write data in which the created parity is attached as a single stripe and then writes the write data together with the created ECC in the NAND flash 11. When the ECC group correction control unit 173b reads the written data, if errors have been detected in a plurality of pieces of the stripe in the read data, the ECC group correction control unit 173b groups ECC creation blocks each of which can be obtained from each piece of the stripe in the read data. Then, the ECC group correction control unit 173b controls the error correction by using the parity for each group. With this configuration, even if errors have been detected from a plurality of pieces of stripe in data that is read from the NAND flash 11, the ECC group correction control unit 173b controls the error correction for each ECC group that is obtained from each piece of stripe in the read data. Consequently, the ECC group correction control unit 173b improves the data recovery rate of the NAND flash 11.

Furthermore, according to the first embodiment described above, if the result of the checked read data obtained by using the ECC indicates that the read data is uncorrectable, the ECC correction control unit 172b outputs a determination result indicating the position of the ECC creation block that is indicated by an ECC and in which an error has been detected. Then, the ECC group correction control unit 173b controls the error correction, by using the parity, in the group that includes the output error position. With this configuration, the ECC group correction control unit 173b can detect a group that includes the position in which the error has been detected and control the error correction within the detected group; therefore, it is possible to improve the data recovery rate of the NAND flash 11.

### [b] Second Embodiment

In the first embodiment described above, a description has been given of a case in which, in the storage device 1, the NAND flash 11, the cache memory 14, the CPU 15, and the memory controller 16 are not duplexed. However, in the storage device 1, the configuration is not limited thereto. For example, the NAND flash 11, the cache memory 14, the CPU 15, and the memory controller 16 may also be duplexed. By doing so, the storage device 1 checks each piece of duplexed read data, thereby it is possible to improve the reliability of the NAND flash 11.

Accordingly, in a second embodiment, a description will be given of a storage device 2 in which the NAND flash 11, the cache memory 14, the CPU 15, and the memory controller 16 are duplexed.

Configuration of a Storage Device According to a Second Embodiment

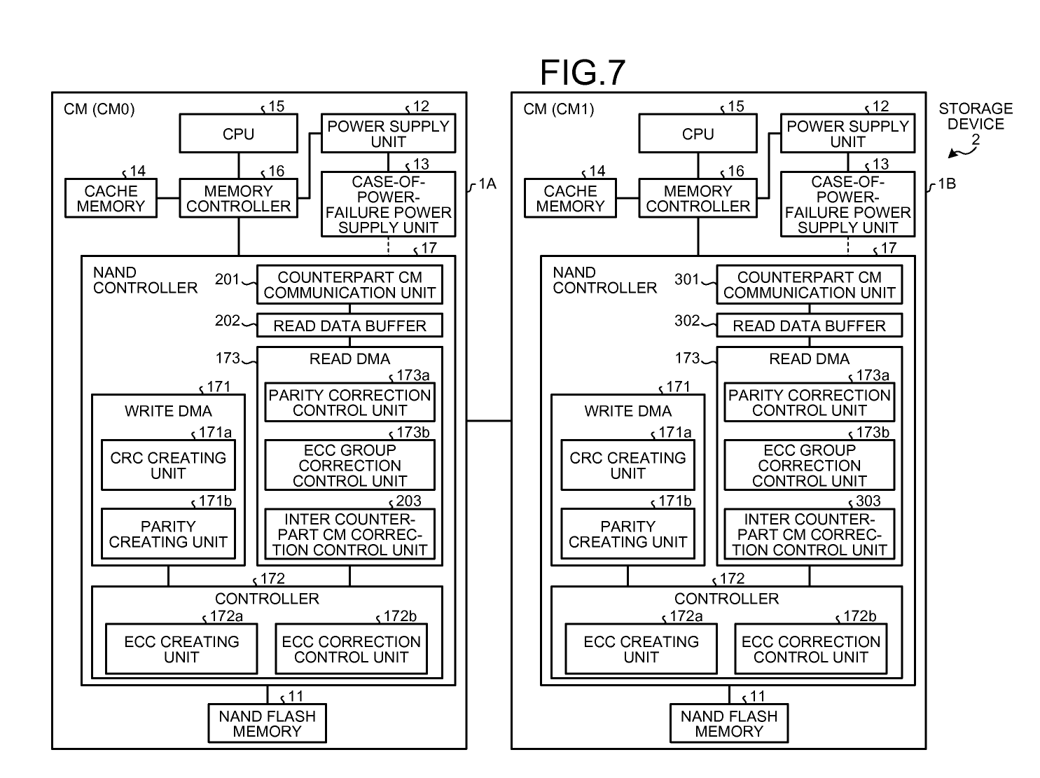

FIG. 7 is a schematic diagram illustrating the hardware configuration of a storage device according to a second embodiment. The components having the same configuration as those in the storage device 1 illustrated in FIG. 1 are assigned the same reference numerals; therefore, descriptions of the overlapped configuration and the operation thereof will be omitted. The second embodiment differs from the first embodiment in that, in the storage device 2, a CM 1A and a CM 1B are duplexed. Each of the CMs includes the NAND flash 11, the power supply unit 12, the case-of-power-failure power supply unit 13, the cache memory 14, the CPU 15, the memory controller 16, and the NAND controller 17. Furthermore, the second embodiment differs from the first embodiment in that a counterpart CM communication unit 201, a read data buffer 202, and an inter counterpart CM correction control unit 203 are added to the NAND controller 17 in the CM 1A. Furthermore, the second embodiment differs from the first embodiment in that a counterpart CM communication unit 301, a read data buffer 302, and an inter counterpart CM correction control unit 303 are added to the NAND controller 17 in the CM 1B.

The counterpart CM communication unit 201 communicates with the other duplexed CM. For example, the counterpart CM communication unit 201 sends, to the CM 1B, the position of an ECC creation block in which an error has been detected in the own CM, i.e., the CM 1A. Furthermore, the counterpart CM communication unit 201 receives the position of an ECC creation block in which an error has been detected in the CM 1B. Furthermore, the counterpart CM communication unit 201 requests the CM 1B to send data on the ECC creation block and receives data in accordance with the request.

The read data that has been read from the NAND flash 11 is stored in the read data buffer 202. For example, in the read data buffer 202, an ECC group that includes an ECC creation block in which an error has been detected. By using the read data buffer 202 having such function, the inter counterpart CM correction control unit 203, which will be described later, cooperates with the counterpart CM communication unit 201 and corrects the ECC creation block in which an error has been detected.

Because the ECC group correction control unit 173b has been described in the first embodiment, a description thereof will be simply given. For example, the ECC group correction control unit 173b detects an ECC group that includes an ECC creation block in which an error has been detected and controls error correction by using a parity included in the detected ECC group. At this point, if an error can be corrected, i.e., if the number of positions of ECC creation blocks in each of which an error has been detected is only one, the ECC group correction control unit 173b corrects the ECC creation block located at the subject position by using the parity that is included in the same group. Furthermore, if errors are uncorrectable, i.e., if the number of positions of ECC creation blocks in each of which an error has been detected is equal to or greater than two, the ECC group correction control unit 173b is not able to correct the error by using the parity that is included in the ECC group.

If the number of positions of ECC creation blocks in each of which an error has been detected in an ECC group is equal to or greater than two, the inter counterpart CM correction control unit 203 uses the data stored in the NAND flash 11 in the counterpart of the duplexed CM 1B and corrects the ECC creation blocks in each of which the error has been detected. For example, the inter counterpart CM correction control unit 203 communicates with the CM 1B by using the counterpart CM communication unit 201 and acquires, in the same ECC group in the read data, the position of the ECC creation block in which an error is present in the CM 1B. Then, the inter counterpart CM correction control unit 203 uses the position of the acquired ECC creation block in which the error has been detected and determines whether an error that is uncorrectable by using ECC has been detected in the CM 1B. If it is determined that an error that is uncorrectable by using ECC is not detected in the CM 1B, because no error is present, the inter counterpart CM correction control unit 203 acquires all of the pieces of the data in the ECC group in the CM 1B by communicating with the CM 1B via the counterpart CM communication unit 201. Then, the inter counterpart CM correction control unit 203 overwrites all of the pieces of the data in the ECC group acquired by the CM 1B onto the data in the ECC group stored in the read data buffer 202.

Furthermore, if the inter counterpart CM correction control unit 203 determines that errors that are uncorrectable by using ECC is detected in the CM 1B, the inter counterpart CM correction control unit 203 checks whether the positions of the ECC creation blocks in each of which the error is present in the same ECC group in the own CM, i.e., the CM 1A, as that in the CM 1B. Then, if the positions of the ECC creation blocks in each of which the error is present do not overlap with any of the same positions or only a single position overlaps with the position, by communicating with the CM 1B via the counterpart CM communication unit 201, the inter counterpart CM correction control unit 203 acquires the ECC creation block that is needed for the correction. Then, the inter counterpart CM correction control unit 203 overwrites the ECC creation block that is needed for the correction and that is acquired from the CM 1B onto the position that is associated with the ECC group stored in the read data buffer 202. Furthermore, the inter counterpart CM correction control unit 203 corrects the error by using the overwritten ECC creation block and by using the ECC creation block that includes therein the parity in the same ECC group. The inter counterpart CM correction control unit 203 is an example of a duplicating unit.

The counterpart CM communication unit 301 communicates with the counterpart duplexed CM. For example, the counterpart CM communication unit 301 receives a request from the CM 1A that is the counterpart CM and sends data in accordance with the request. The request mentioned here is, for example, a request for data in the subject ECC creation block to be sent or a request for the position of the ECC creation block in which an error is present to be sent.

In the read data buffer 302, read data that is read from the NAND flash 11 is stored. The read data buffer 302 has the same function as that performed by the read data buffer 202; therefore, a description thereof will be omitted.

If the number of the positions of the ECC creation blocks in each of which an error has been detected is equal to or greater than two, by using the data stored in the NAND flash 11 in the counterpart duplexed CM 1A, the inter counterpart CM correction control unit 303 corrects the ECC creation block in which an error has been detected. The process performed by the inter counterpart CM correction control unit 303 is the same as that performed by the inter counterpart CM correction control unit 203; therefore, a description thereof will be omitted.

Specific Example of Data Correction

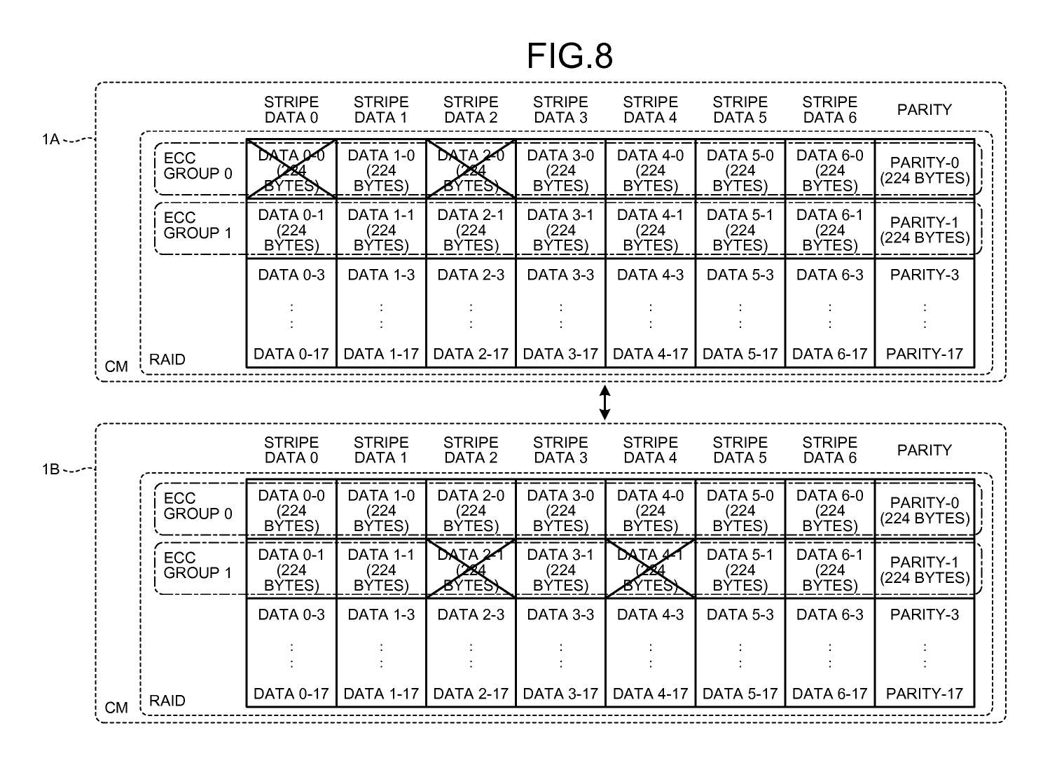

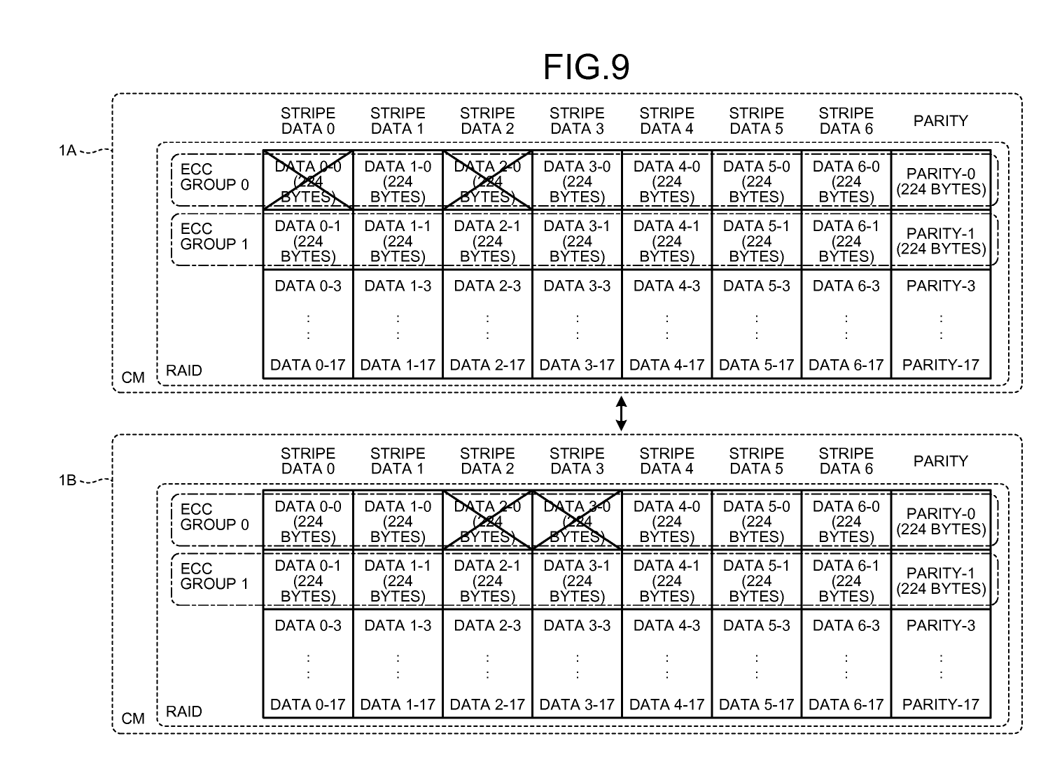

In the following, a specific example of data correction according to the second embodiment will be described with reference to FIGS. 8 and 9. FIGS. 8 and 9 are schematic diagrams each illustrating a specific example of data correction according to the second embodiment.

As illustrated in FIG. 8, it is assumed that the error in the ECC group 0 in the CM 1A is uncorrectable. Namely, it is assumed that the positions of the ECC creation blocks in each of which an error has been detected in the ECC group 0 are data 0-0 and data 2-0, the number of which is equal to or greater than two. In contrast, it is assumed that no error was detected in the ECC group 0 in the counterpart duplexed CM 1B.

With this state, because, in the CM 1B, no error is present in the same ECC group as the ECC group 0 that is included in the CM 1A and in which the error has been detected, the inter counterpart CM correction control unit 203 in the CM 1A acquires all of the pieces of the data stored in the ECC group 0 in the CM 1B. Then, the inter counterpart CM correction control unit 203 overwrites all of the pieces of the data stored in the ECC group 0 acquired from the CM 1B onto the data in the ECC group 0 stored in the read data buffer 202. By doing so, by using data, in which no error is present, in the ECC group 0 in the counterpart CM 1B, the inter counterpart CM correction control unit 203 can correct the ECC group 0 in which the errors are uncorrectable in the CM 1A.

Furthermore, it is assumed that errors in the ECC group 1 in the CM 1B are uncorrectable. Namely, it is assumed that the positions of the ECC creation blocks in each of which an error has been detected in the ECC group 1 are data 2-1 and data 4-1, the number of which is equal to or greater than two. In contrast, it is assumed that no error was detected in the ECC group 1 in the counterpart duplexed CM 1A.

In this state, because, in the CM 1A, no error is present in the same ECC group as the ECC group 1 that is included in the CM 1B and in which the error has been detected, the inter counterpart CM correction control unit 303 in the CM 1B acquires all of the pieces of the data stored in the ECC group 1 in the CM 1A. Then, the inter counterpart CM correction control unit 303 overwrites all of the pieces of the data stored in the ECC group 1 acquired from the CM 1A onto the data in the ECC group 1 stored in the read data buffer 302. By doing so, by using data that contains no error in the ECC group 1 in the counterpart CM 1A, the inter counterpart CM correction control unit 303 can correct the ECC group 1 in which the errors are uncorrectable in the CM 1B.

As illustrated in FIG. 9, it is assumed that the errors in the ECC group 0 in the CM 1A are uncorrectable. Namely, it is assumed that the positions of the ECC creation blocks in each of which an error has been detected in the ECC group 0 are data 0-0 and data 2-0, the number of which is equal to or greater than two. In contrast, it is assumed that errors in the ECC group 0 in the CM 1B are uncorrectable. Namely, it is assumed that the position of the ECC creation blocks in each of which an error has been detected in the ECC group 0 are data 2-0 and data 3-0, the number of which is equal to or greater than two.

In this state, the inter counterpart CM correction control unit 203 in the CM 1A checks whether the positions of the ECC creation blocks in each of which an error is present do not overlap with any of the same positions or only a single position overlaps. In this case, because the pieces of the data 2-0 overlap but the data 0-0 and the data 3-0 do not overlap, the inter counterpart CM correction control unit 203 determines that only a single position overlaps. Accordingly, the inter counterpart CM correction control unit 203 acquires the data 0-0 that is needed for the correction from the CM 1B and overwrites the acquired data 0-0 onto the data 0-0 in the ECC group 0 stored in the read data buffer 202. Then, the inter counterpart CM correction control unit 203 corrects the data 2-0 by using the data in the ECC creation block that includes the parity-0 in the ECC group 0. By doing so, by using the data that does not includes an error in the ECC group 0 in the counterpart CM 1B, the inter counterpart CM correction control unit 203 can correct the ECC group 0 in which the errors are uncorrectable in the CM 1A.

Furthermore, the inter counterpart CM correction control unit 303 in the CM 1B acquires the data 3-0 that is needed for the correction from the CM 1A and overwrites the acquired data 3-0 onto the data 3-0 in the ECC group 0 that is stored in the read data buffer 302. Then, the inter counterpart CM correction control unit 303 corrects the data 2-0 by using the data in the ECC creation block that includes therein the parity-0 in the ECC group 0. By doing so, by using the data in which no error is present in the ECC group 0 in the counterpart CM 1A, the inter counterpart CM correction control unit 303 can correct the ECC group 0 in which the errors are uncorrectable in the CM 1B.

Flowchart of the Data Correction Process

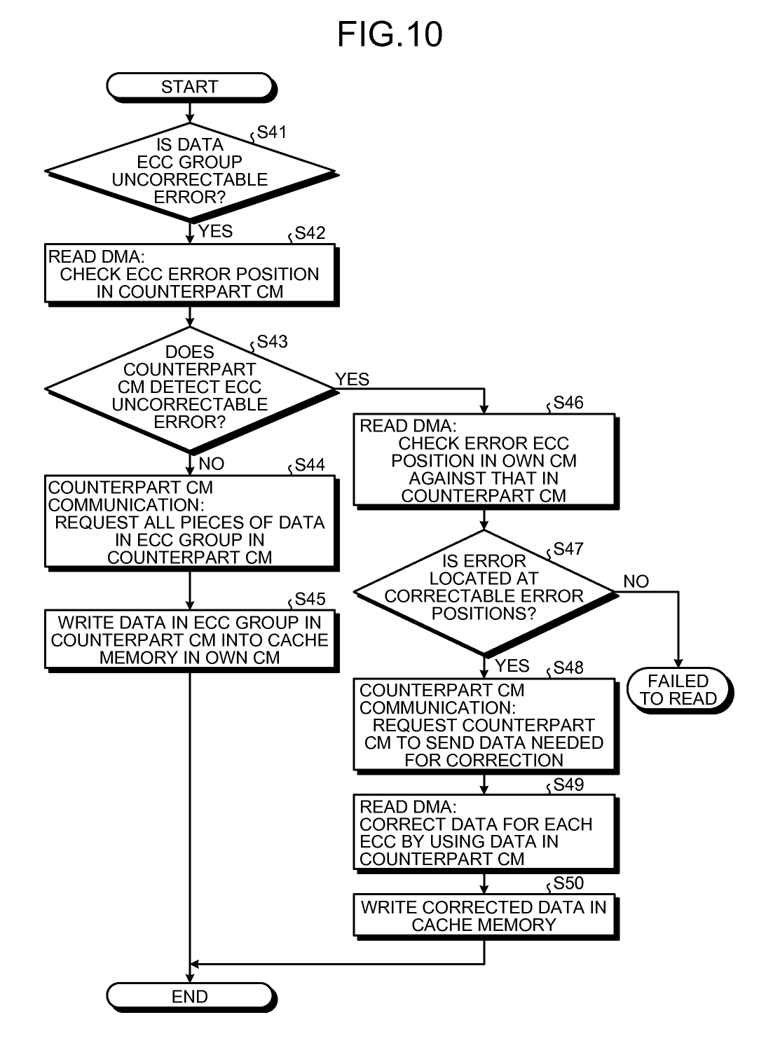

In the following, the data correction process according to the second embodiment will be described with reference to FIG. 10. Here, a description will be given of an example of a process that corrects, if a read instruction of data from the server 9 is issued, the data that has been read from the NAND flash 11 in accordance with the read instruction. In addition, in FIG. 10, a description will be given of a correction process that is performed on the ECC group that stores therein an error (mistake) in the flowchart of the data correction process illustrated in FIG. 6 does not corresponds to the ECC group correctable error (No at Step S32). The ECC group correctable error mentioned here is a correctable error in an ECC group.

First, in FIG. 6, the ECC group correction control unit 173b in the read DMA 173 determines whether an ECC group correctable error is present in the ECC group in which an error (mistake) has been detected (Step S32). Namely, the ECC group correction control unit 173b determines whether the number of ECC creation blocks in each of which an error is present in an ECC group is equal to or greater than two. If it is determined that the ECC group correctable errors are present (Yes at Step S32), the ECC group correction control unit 173b corrects, for the ECC group in which the errors are present, the data in each of the ECC creation blocks (Step S33).

In contrast, if it is determined that no ECC group correctable errors are present (No at Step S32), the ECC group correction control unit 173b determines whether, for the ECC group in which an error is present, the errors are the ECC group uncorrectable errors (Step S41). The ECC group uncorrectable error mentioned here is an uncorrectable error in an ECC group. If it is determined that the errors are the ECC group uncorrectable errors (Yes at Step S41), the inter counterpart CM correction control unit 203 in the read DMA 173 checks the position of the ECC creation block in which an error has been detected in the counterpart CM (Step S42).

Subsequently, after the checking, for the same ECC group as the ECC group in which the error is present, the inter counterpart CM correction control unit 203 determines whether an ECC uncorrectable error has been detected in the counterpart CM 1B (Step S43). The ECC uncorrectable error mentioned here is an uncorrectable error that is uncorrectable by ECC in the ECC group in which an error has been detected. If it is determined that an ECC uncorrectable error has been detected in the counterpart CM 1B (Yes at Step S43), the inter counterpart CM correction control unit 203 proceeds to Step S46.

In contrast, if it is determined that no ECC uncorrectable error has been detected in the counterpart CM 1B (No at Step S43), the counterpart CM communication unit 201 requests all of the pieces of data in the ECC group in the counterpart CM 1B (Step S44).

Then, the inter counterpart CM correction control unit 203 writes, via the memory controller 16, the data in the ECC group in the counterpart CM 1B into the cache memory 14 in the own CM, i.e., the CM 1A (Step S45). For example, the inter counterpart CM correction control unit 203 acquires all of the pieces of the data in the ECC group in the counterpart CM 1B acquired in accordance with the request. Then, the inter counterpart CM correction control unit 203 overwrites the acquired all of the pieces of the data in the ECC group onto the data in the ECC group stored in the read data buffer 202. Then, the inter counterpart CM correction control unit 203 writes the overwritten data in the ECC group in the read data buffer 202 into the cache memory 14 via the memory controller 16 and then outputs the read data to the server 9. Consequently, the process has been ended as the completion of the reading process.

At Step S46, the inter counterpart CM correction control unit 203 in the read DMA 173 checks the position of the ECC creation block in which an error has been detected in the own CM against the counterpart CM 1B (Step S46). Then, after the checking, the inter counterpart CM correction control unit 203 determines whether the positions of the ECC creation blocks in each of which the error has been detected are correctable error positions (Step S47). Namely, the inter counterpart CM correction control unit 203 determines whether the positions of the ECC creation blocks in each of which an error has been detected in the own CM and the counterpart CM 1B do not overlap at all or a single position only overlaps in the own CM and the counterpart CM 1B.

If it is determined that the positions of the ECC creation blocks in each of which the error has been detected are not correctable error positions (No at Step S47), the inter counterpart CM correction control unit 203 determines that the error is uncorrectable in the ECC group in which the error is present. Consequently, the process is ended as a failure to read data.

In contrast, if it is determined that the positions of the ECC creation blocks in each of which an error has been detected is correctable error positions (Yes at Step S47), the counterpart CM communication unit 201 requests the ECC creation block that is needed for data correction from the counterpart CM 1B (Step S48). Then, the inter counterpart CM correction control unit 203 in the read DMA 173 uses the data in the counterpart CM 1B and corrects, for each ECC creation block, the pieces of the data in each of which an error has been detected in the ECC group (Step S49). For example, the inter counterpart CM correction control unit 203 acquires an ECC creation block that is needed for the correction in the counterpart CM 1B obtained in accordance with the request. Then, the inter counterpart CM correction control unit 203 overwrites the acquired ECC creation block onto the position that is associated with the ECC group stored in the read data buffer 202. Then, by using the overwritten ECC creation block and the ECC creation blocks including the parity in the ECC group, the inter counterpart CM correction control unit 203 corrects the ECC creation block in which an error has been detected.

Then, the inter counterpart CM correction control unit 203 writes, via the memory controller 16, the corrected data in the ECC group into the cache memory 14 in the own CM (Step S50) and then outputs the read data to the server 9. Consequently, the process is ended as the completion of the reading process.

By doing to, the user data that is written in the NAND flash 11 is correctly written in the cache memory 14 even if an error is present in the reading process. Furthermore, the memory controller 16 can convey the correct user data to the server 9.

### Advantage of the Second Embodiment

According to the second embodiment described above, if several positions of ECC creation blocks in each of which an error has been detected are present in an ECC group, the inter counterpart CM correction control unit 203 uses the data stored in the NAND flash 11 in the CM 1B that is duplexed with the own CM and corrects the ECC creation blocks that are located at the error positions. Namely, if, in the CM 1B, no error is present in the ECC creation block that is located at the same position as the error position, by overwriting the ECC creation block in which no error is present onto the position the error is present in the own CM, the inter counterpart CM correction control unit 203 corrects the ECC creation block at the position in which the error has been detected. With this configuration, the inter counterpart CM correction control unit 203 can correct the error, in the ECC creation block in which the error has been detected, by using the ECC creation block that contains therein no error and that is included in the CM 1B that is duplexed with the own CM. Consequently, it is possible to further improve the data recovery rate of the NAND flash 11.

Additional

In the first and the second embodiments, a description has been given of a case in which each of the storage devices 1 and 2 uses the NAND flash 11 as a storage medium in which data received from the server 9 is to be stored. However, each of the storage devices 1 and 2 may also use the NAND flash 11 as the storage medium at the backup destination that is used when a power failure occurs. In such a case, each of the storage devices 1 and 2 may have mounted thereon a hard disk drive (HDD) as a storage medium at the storage destination of the data received from the server 9. For example, a RAID controller is connected to the memory controller 16 and each of the storage devices 1 and 2 has mounted thereon the HDD that is managed by the RAID controller. With this configuration, in the normal operation, the cache memory 14 temporarily stores user data that is to be written in the HDD in accordance with a write instruction from the server 9. Furthermore, in the normal operation, the cache memory 14 temporarily stores user data that is read from the HDD in accordance with the read instruction from the server 9. Then, when a power failure occurs, the memory controller 16 performs a backup process in which the user data that is temporarily stored in the cache memory 14 is stored in the NAND flash 11. Then, when the power failure is recovered, the memory controller 16 writes the read data that was output from the read DMA 173 back to the cache memory 14. Even with this configuration, the user data that was temporarily stored in the cache memory 14 can be saved in the NAND flash 11 at the time of the power failure. Then, the user data that was saved in the NAND flash 11 at the time of recovery of the power failure can be correctly written back to the cache memory 14 at the time of recovery of the power failure.

Furthermore, the components in each of the storage devices 1 and 2 illustrated in the drawings are not always physically configured as illustrated in the drawings. In other words, the specific shape of a separate or integrated of each of the storage devices 1 and 2 is not limited to the drawings; however, all or part of the crossbar switch can be configured by functionally or physically separating or integrating any of the units, such as integrating embedding units, depending on various loads or use conditions. For example, the CRC creating unit 171a and the parity creating unit 171b may also be integrated with a single unit, such as an error code creating unit. The ECC group correction control unit 173b and the inter counterpart CM correction control unit 203 may also be integrated with a single unit, such as an ECC group correction control unit. In contrast, the parity correction control unit 173a may also be separated into a CRC checking unit and a parity correction control unit.

According to an aspect of the embodiments of the device disclosed in the present invention, an advantage is provided in that the data recovery rate of the storage medium can be improved.

All examples and conditional language provided herein are intended for the pedagogical purposes of aiding the reader in understanding the invention and the concepts contributed by the inventors to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A recording and reproducing device comprising:
a plurality of data storing units;
a control unit that creates stripe data with a predetermined write capacity by attaching a first error correction code to write data, that creates a redundant group by attaching a second error correction code to a predetermined number of pieces of the stripe data, that associates a plurality of pieces of stripe data belonging to the same redundant group with the second error correction code, and that controls the writing of the associated data into each of the plurality of the data storing units;
a first error detection-and-correction unit that detects, by using the second error correction code, whether an error is present in each of the pieces of the stripe data, which are read from each of the data storing units and belong to the same redundant group, and that corrects the stripe data in which the error is present; and
a second error detection-and-correction unit that groups, for creation blocks of the first error correction code, the second error correction code and the pieces of the stripe data that are read from each of the data storing units and that belong to the same redundant group, that creates a plurality of error correction groups each of which includes a plurality of pieces of split stripe data and a split second error correction code, that detects, by using the split second error correction code, whether an error is present in each of the pieces of the split stripe data in the same error correction group, and that corrects the split stripe data in which the error is present.

2. The recording and reproducing device according to claim 1, further including an error position output unit that detects, by using the first error correction code, whether an error is present in data that belongs to the same redundant group read from each of the plurality of the data storing units and that outputs, when data in which an error is present is uncorrectable, a detected position of the error present in a creation block of the first error correction code, wherein
the second error detection-and-correction unit corrects the split stripe data in which the error is present in an error correction group that includes the error position that is output by the error position output unit.

3. The recording and reproducing device according to claim 2, further including a duplicating unit that receives, when a plurality of error positions are present in the error correction group and when, from among pieces of data stored in a plurality of data storing units that are included in the recording and reproducing device and in a redundant device, no error is present in split stripe data that belongs to a group associated with the error correction group and that is located at the same position as the error position in the recording and reproducing device, the split stripe data in which no error is present and that duplicates the received split stripe data onto a corresponding error position in the recording and reproducing device.

4. An error correction method comprising:
creating stripe data with a predetermined write capacity by attaching a first error correction code to write data, and creating a redundant group by attaching a second error correction code to a predetermined number of pieces of the stripe data;
associating a plurality of pieces of stripe data belonging to the same redundant group with the second error correction code;
controlling the writing of the associated data into each of a plurality of data storing units;
detecting, performed by the data error correction device, by using the second error correction code, whether an error is present in the pieces of the stripe data, which are read from each of the data storing units and belong to the same redundant group, and correcting, performed by the data error correction device, the stripe data in which the error is present; and
grouping, performed by the data error correction device, for creation blocks of the first error correction code, the second error correction code and the pieces of the stripe data that are read from each of the data storing units and that belong to the same redundant group, creating, performed by the data error correction device, a plurality of error correction groups each of which includes a plurality of pieces of split stripe data and a split second error correction code, and detecting, performed by the data error correction device, by using the split second error correction code, whether an error is present in each of the pieces of the split stripe data in the same error correction group, and correcting, performed by the data error correction device, the split stripe data in which the error is present.

5. A control device comprising:
a control unit that controls writing of data into a plurality of data storing units and reading of data from the plurality of the data storing units, that creates stripe data with a predetermined write capacity by attaching a first error correction code to write data, that creates a redundant group by attaching a second error correction code to a predetermined number of pieces of the stripe data, that associates a plurality of pieces of stripe data belonging to the same redundant group with the second error correction code, and that controls the writing of the associated data into each of the plurality of the data storing units;
a first error detection-and-correction unit that detects, by using the second error correction code, whether an error is present in each of the pieces of the stripe data, which are read from each of the data storing units and belong to the same redundant group, and that corrects the stripe data in which the error is present; and
a second error detection-and-correction unit that groups, for creation blocks of the first error correction code, the second error correction code and the pieces of the stripe data that are read from each of the data storing units and that belong to the same redundant group, that creates a plurality of error correction groups each of which includes a plurality of pieces of split stripe data and a split second error correction code, that detects, by using the split second error correction code, whether an error is present in each of the pieces of the split stripe data in the same error correction group, and that corrects the split stripe data in which the error is present.
